(19) United States
(12) Patent Application Publication
(10) Pub. No.: US 2025/0048905 A1
(43) Pub. Date: Feb. 6, 2025

(54) DISPLAY APPARATUS

(71) Applicant: Samsung Display Co., LTD., Yongin-si (KR)

(72) Inventors: Kyeongjong KIM, Yongin-si (KR); Yunhee PARK, Yongin-si (KR); Yiseop SHIM, Yongin-si (KR); Hyunseung LEE, Yongin-si (KR); Kyuwon CHO, Yongin-si (KR); Kyungseon TAK, Yongin-si (KR)

(21) Appl. No.: 18/734,959

(22) Filed: Jun. 5, 2024

(30) Foreign Application Priority Data
Aug. 3, 2023 (KR) 10-2023-0101743

(51) Int. Cl. H10K 59/80; H10K 59/38

(52) U.S. Cl. CPC H10K 59/8792; H10K 59/38

(57) ABSTRACT

A display apparatus includes a first light-emitting diode disposed in a first emission area, a second light-emitting diode disposed in a second emission area, a color converting-transmitting layer including a color conversion portion and a light blocking partition wall surrounding the color conversion portion, where the color conversion portion converts light emitted from one of the first light-emitting diode and the second light-emitting diode into light of a different color, a first color filter disposed on the color converting-transmitting layer corresponding to the first emission area, a second color filter corresponding to the second emission area, a third color material covering a first end portion of the first color filter and a first end portion of the second color filter, and a color adjustment layer disposed on the color converting-transmitting layer corresponding to the light blocking partition wall.

This application claims priority to Korean Patent Application No. 10-2023-0101743, filed on Aug. 3, 2023, and all the benefits accruing therefrom under 35 U.S.C. § 119, the content of which in its entirety is herein incorporated by reference.

### BACKGROUND

### 1. Field

One or more embodiments relate a display apparatus capable of displaying high quality images.

### 2. Description of the Related Art

With the rapid development in the display field of visually displaying various pieces of electrical signal information, various display apparatuses with various desired characteristics, such as thinness, lightness, and low power consumption, have been introduced.

Display apparatuses may include liquid crystal display apparatuses that do not emit light by themselves, but use light of a backlight, and light-emitting display apparatuses that include display elements capable of emitting light. A light-emitting display apparatus may include display elements each including an emission layer.

### SUMMARY

One or more embodiments include a display apparatus, and in detail, a structure for a light-emitting display apparatus.

According to one or more embodiments, a display apparatus includes a first light-emitting diode located in a first emission area, a second light-emitting diode located in a second emission area, an encapsulation layer disposed on the first light-emitting diode and the second light-emitting diode, where the encapsulation layer includes at least one inorganic encapsulation layer and at least one organic encapsulation layer, a color converting-transmitting layer disposed on the encapsulation layer, and including a color conversion portion and a light blocking partition wall surrounding the color conversion portion, where the color conversion portion converts light emitted from one of the first light-emitting diode and the second light-emitting diode into light of a different color, a first color filter disposed on the color converting-transmitting layer corresponding to the first emission area, a second color filter disposed on the color converting-transmitting layer and corresponding to the second emission area, a third color material covering a first end portion of the first color filter and a first end portion of the second color filter, and a color adjustment layer disposed on the color converting-transmitting layer corresponding to the light blocking partition wall.

In an embodiment, the height of the color adjustment layer may be less than the height of a central portion of the first color filter and the height of a central portion of the second color filter.

In an embodiment, the height of the color adjustment layer may be about 1 micrometer (μm) or less.

In an embodiment, the color adjustment layer may include a first color material of the first color filter, a second color material of the second color filter, and a fourth color material having a color different from the third color material.

In an embodiment, the color adjustment layer may include a yellow pigment or dye.

In an embodiment, in a visible light wavelength band of about 380 nanometers (nm) to about 780 nm, a reflectivity of the third color material may be less than a reflectivity of each of a first color material of the first color filter and a second color material of the second color filter.

In an embodiment, the color adjustment layer may overlap at least a part of the third color material.

In an embodiment, the display apparatus may further include an insulating layer disposed on the color converting-transmitting layer, where a lower surface of the first color filter, a lower surface of the second color filter, and a lower surface of the color adjustment layer may be in direct contact with the insulating layer.

In an embodiment, a first end portion of the first color filter and a first end portion of the second color filter may be spaced apart from each other with a gap therebetween while overlapping the light blocking partition wall, and a part of the third color material may be at least partially disposed in the gap.

In an embodiment, the color adjustment layer may overlap at least a part of the third color material.

In an embodiment, the display apparatus may further include an overcoat layer disposed on the first color filter and the second color filter, where a lower surface of the overcoat layer may include a concave surface corresponding to a convex surface included in an upper surface of the third color material.

In an embodiment, the color adjustment layer may be disposed between the third color material and the overcoat layer.

In an embodiment, the color conversion portion may include quantum dots.

According to one or more embodiments, a display apparatus includes a light-emitting diode layer including a first light-emitting diode disposed in a first emission area, a second light-emitting diode disposed in a second emission area, and a third light-emitting diode disposed in a third emission area, an encapsulation layer disposed on the light-emitting diode layer, where the encapsulation layer includes at least one inorganic encapsulation layer and at least one organic encapsulation layer, a first color filter disposed on the encapsulation layer and corresponding to the first emission area, a second color filter disposed on the encapsulation layer and corresponding to the second emission area, a third color filter disposed on the encapsulation layer and corresponding to the third emission area, a third color material covering a first end portion of the first color filter and a first end portion of the second color filter and having a same color as the third color filter, and a color adjustment layer disposed on the encapsulation layer, where the color adjustment layer defines a first opening corresponding to the first emission area, a second opening corresponding to the second emission area, and a third opening corresponding to the third emission area, and the color adjustment layer is disposed to overlap the third color material.

In an embodiment, the color adjustment layer may have a color different from the first color filter, the second color filter, and the third color filter.

In an embodiment, the height of the color adjustment layer may be about 1 μm or less.

In an embodiment, the color adjustment layer may include a yellow pigment or dye.

In an embodiment, a refractive index of the third color material may be less than a refractive index of the first color filter and a refractive index of the second color filter.

In an embodiment, the display apparatus may further include an insulating layer disposed on the encapsulation layer, where a lower surface of the first color filter, a lower surface of the second color filter, a lower surface of the third color filter, and a lower surface of the color adjustment layer may be in direct contact with the insulating layer.

In an embodiment, the display apparatus may further include an overcoat layer disposed on the third color material, where the color adjustment layer may be disposed between the third color material and the overcoat layer.

Other features of embodiments of the invention than those described above will become apparent from the following drawings, claims, and detailed description of the disclosure.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of respective pixels of a display apparatus according to an embodiment;

FIG. 3 illustrates respective optical portions of the color converting-transmitting layer of FIG. 2;

FIG. 4 is an equivalent circuit diagram of a light-emitting diode and a pixel circuit electrically connected to the light-emitting diode, which are included in a display apparatus according to an embodiment;

FIGS. 5 to 12 are cross-sectional views showing a method of manufacturing a display apparatus, according to an embodiment;

FIG. 13A is a plan view of a color adjustment layer formed in a method of manufacturing a display apparatus, according to an embodiment;

FIG. 13B is a plan view showing a process of forming a first color layer on the color adjustment layer;

FIG. 13C is a plan view showing a process of forming a second color layer after the first color layer is formed;

FIG. 13D is a plan view showing a process of forming a third color layer after the second color layer is formed; and

FIG. 14 is a schematic cross-sectional view of a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. “ ” “ ”

Hereinafter, embodiments will be described in detail with reference to the accompanying drawings, and in the description with reference to the drawings, the same or corresponding elements are indicated by the same reference numerals and any repetitive detailed descriptions thereof may be omitted or simplified.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items “ ” “ ”. Throughout the disclosure, the expression “at least one of a, b or c” or “at least one selected from a, b and c” indicates only a, only b, only c, both a and b, both a and c, both b and c, all of a, b, and c, or variations thereof.

In the following embodiment, it will be further understood that the terms “comprises” and/or “comprising” or “includes” and/or “including” when used in this specification, specify the presence of stated features or regions, integers, steps, operations, elements, and/or components, but do not preclude the presence or addition of one or more other features or regions, integers, steps, operations, elements, and/or components.

It will be understood that when an element is referred to as being “on” another element, it can be directly on the other element or intervening elements may be present therebetween. In contrast, when an element is referred to as being “directly on” another element, there are no intervening elements present””.

Sizes of elements in the drawings may be exaggerated for convenience of explanation. For example, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the following embodiment, when a layer, area, or component is connected to another layer, area, or component, it can be directly connected to the other layer, region, or component or indirectly connected to the other layer, region, or component via intervening layers, regions, or components. For example, in the disclosure, when a layer, region, or component is referred to as being electrically connected to another layer, region, or component, it can be directly electrically connected to the other layer, region, or component or indirectly electrically connected to the other layer, region, or component via intervening layers, regions, or components.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

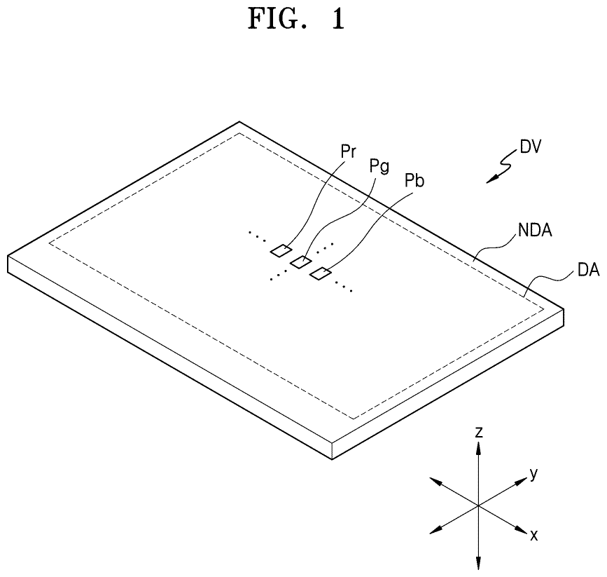

FIG. 1 is a schematic perspective view of a display apparatus DV according to an embodiment.

Referring to FIG. 1, an embodiment of the display apparatus DV may include a display area DA and a non-display area NDA outside the display area DA. The display apparatus DV may provide an image through an array of a plurality of pixels two-dimensionally arranged on an x-y plane in the display area DA. The pixels include first pixels, second pixels, and third pixels. In the following description, for convenience of description, embodiments where the first pixel is a red pixel Pr, the second pixel is a green pixel Pg, and the third pixel is a blue pixel Pb will be described in detail.

The red pixel Pr, the green pixel Pg, and the blue pixel Pb are respectively areas for emitting red, green, and blue light, and thus, the display apparatus DV may provide an image using the light emitted from the pixels.

The non-display area NDA, which is an area that does not provide an image, may entirely surround the display area DA. A driver or main power line for providing electrical signals or power to pixel circuits may be arranged in the non-display area NDA. The non-display area NDA may include a pad that is an area to which electronic devices or printed circuit boards may be electrically connected.

The display area DA may have a polygonal shape including a rectangle, as illustrated in FIG. 1. In an embodiment, for example, the display area DA may have a rectangular shape in which a horizontal length is greater than a vertical length, a rectangular shape in which a horizontal length is less than a vertical length, or a square shape. Alternatively, the display area DA may have various shapes, such as an oval or a circle.

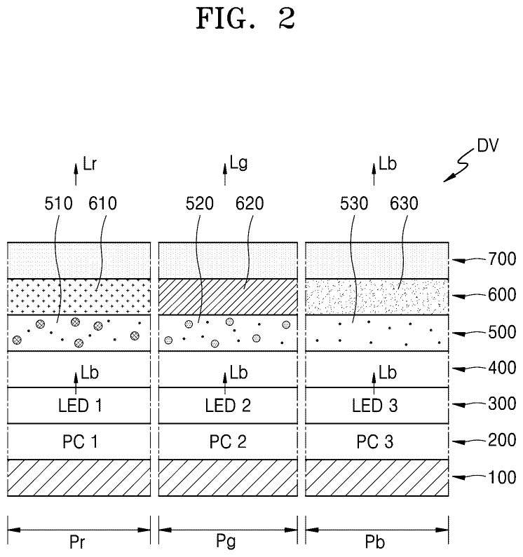

FIG. 2 is a schematic cross-sectional view of respective pixels of the display apparatus DV according to an embodiment.

Referring to FIG. 2, an embodiment of the display apparatus DV may include a circuit layer 200 on a substrate 100. The circuit layer 200 includes first to third pixel circuits PC1, PC2, and PC3, and the first to third pixel circuits PC1, PC2, and PC3 may be electrically connected to first to third light-emitting diodes LED1, LED2, and LED3 of a light-emitting diode layer 300, respectively.

The first to third light-emitting diodes LED1, LED2, and LED3 may each include an organic light-emitting diode including an organic material. In another embodiment, the first to third light-emitting diodes LED1, LED2, and LED3 may include an inorganic light-emitting diode including an inorganic material. The inorganic light-emitting diode may include a PN junction diode including inorganic material semiconductor-based materials. When a voltage is applied to the PN junction diode in a forward direction, holes and electrons are injected, and energy generated according to a recombination of the holes and the electrons is converted into light energy so that light of a certain color may be emitted. The inorganic light-emitting diode described above may have a width of several to hundreds of micrometers or several to hundreds of nanometers. In some embodiments, a light-emitting diode LED may be a light-emitting diode including quantum dots. As described above, an emission layer of the light-emitting diode LED may include an organic material, an inorganic material, quantum dots, an organic material and quantum dots, or an inorganic material and quantum dots.

The first to third light-emitting diodes LED1, LED2, and LED3 may emit light of a same color. In an embodiment, for example, the light (e.g., blue light Lb) emitted from the first to third light-emitting diodes LED1, LED2, and LED3 may pass through an encapsulation layer 400 on the light-emitting diode layer 300 and then pass through a color converting-transmitting layer 500.

The color converting-transmitting layer 500 may include optical portions that convert the color of the light (e.g., blue light Lb) emitted from the light-emitting diode layer 300, or transmit the light without any color conversion. In an embodiment, for example, the color converting-transmitting layer 500 may include color conversion portions that convert the light (e.g., blue light Lb) emitted from the light-emitting diode layer 300 into light of a different color, and a transmitting portion that transmits, without color conversion, the light (e.g., blue light Lb) emitted from the light-emitting diode layer 300. In an embodiment, for example, the color converting-transmitting layer 500 may include a first color conversion portion 510 corresponding to the red pixel Pr, a second color conversion portion 520 corresponding to the green pixel Pg, and a transmitting portion 530 corresponding to the blue pixel Pb. The first color conversion portion 510 may convert the blue light Lb into red light Lr, and the second color conversion portion 520 may convert the blue light Lb into green light Lg. The transmitting portion 530 may transmit the blue light Lb without conversion.

A color layer 600 may be disposed on the color converting-transmitting layer 500. The color layer 600 may include first to third color filters 610, 620, and 630 of different colors. In an embodiment, for example, the first color filter 610 may be a red color filter, and the second color filter 620 may be a green color filter, and the third color filter 630 may be a blue color filter.

The light that is color-converted in the color converting-transmitting layer 500 or the light that is transmitted through the color converting-transmitting layer 500 pass through a corresponding one of the first to third color filters 610, 620, and 630, and color purity of the light may be improved. Furthermore, the color layer 600 may effectively prevent or substantially reduce the external light (e.g., light incident on the display apparatus DV from the outside of the display apparatus DV) from being reflected and perceived by a user.

An overcoat layer 700 for planarizing the upper surface of the color layer 600 may be disposed on the color layer 600. The overcoat layer 700 may include a light-transmissive organic material. In an embodiment, for example, the overcoat layer 700 may include a light-transmissive organic material such as acrylic resin. The overcoat layer 700 may be formed by being directly coated and cured on the color layer 600, and in a thickness direction (a z direction) of the display apparatus DV, may be disposed farther from the light-emitting diode layer 300 than the color layer 600.

Although not illustrated, another optical film, for example, an anti-reflection (AR) film, or the like, may be disposed on the overcoat layer 700.

The display apparatus DV having the structure described above may include a mobile phone, a television, a billboard, a monitor, a tablet personal computer (PC), a notebook computer, and the like.

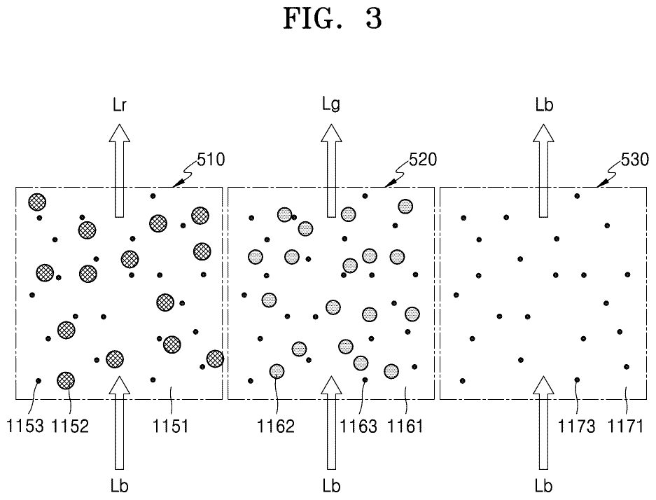

FIG. 3 illustrates respective optical portions of the color converting-transmitting layer 500 of FIG. 2.

Referring to FIG. 3, in an embodiment, the first color conversion portion 510 may convert the blue light Lb that is incident into the red light Lr. The first color conversion portion 510 may include, as illustrated in FIG. 3, a first photosensitive polymer 1151, and first quantum dots 1152 and first scattering particles 1153 both dispersed in the first photosensitive polymer 1151.

The first quantum dots 1152 may be excited by the blue light Lb to isotropically emit the red light Lr having a wavelength longer than that of the blue light Lb. The first photosensitive polymer 1151 may include an organic material having light transmissivity. The first scattering particles 1153 may scatter the blue light Lb that is not absorbed by the first quantum dots 1152 so that a greater number of the first quantum dots 1152 are exited, thereby increasing color conversion efficiency. The first scattering particles 1153 may be, for example, a titanium oxide (TiO₂), metal particles, or the like. The first quantum dots 1152 may be selected from group II-VI compounds, group Ill-V compounds, group IV-VI compounds, group IV elements, group IV compounds, and a combination thereof.

The second color conversion portion 520 may convert the blue light Lb that is incident into the green light Lg. The second color conversion portion 520 may include, as illustrated in FIG. 3, a second photosensitive polymer 1161, and second quantum dots 1162 and second scattering particles 1163 both dispersed in the second photosensitive polymer 1161.

The second quantum dots 1162 may be excited by the blue light Lb to isotropically emit the green light Lg having a wavelength longer than that of the blue light Lb. The second photosensitive polymer 1161 may include an organic material having light transmissivity.

The second scattering particles 1163 may scatter the blue light Lb that is not absorbed by the second quantum dots 1162 so that a greater number of the second quantum dots 1162 are excited, thereby increasing color conversion efficiency. The second scattering particles 1163 may be, for example, a TiO₂, metal particles, or the like. The second quantum dots 1162 may be selected from group II-VI compounds, group III-V compounds, group IV-VI compounds, group IV elements, group IV compounds, and a combination thereof.

In some embodiments, the first quantum dots 1152 and the second quantum dots 1162 may include a same material as each other. In such embodiments, the size of each of the first quantum dots 1152 may be greater than the size of each of the second quantum dots 1162.

The transmitting portion 530 may transmit the blue light Lb incident thereon, without any light conversion thereof. The transmitting portion 530 may include, as illustrated in FIG. 3, a third photosensitive polymer 1171 in which third scattering particles 1173 are dispersed. The third photosensitive polymer 1171 may include, for example, an organic material having light transmissivity, such as silicon resin, epoxy resin, or the like, and have the same material as those of the first and second photosensitive polymers 1151 and 1161. The third scattering particles 1173 may scatter the blue light Lb to be emitted, and may include a same material as those of the first and second scattering particles 1153 and 1163.

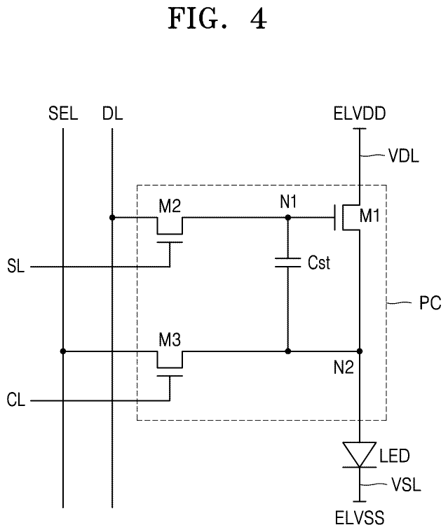

FIG. 4 is an equivalent circuit diagram of the light-emitting diode LED and a pixel circuit PC electrically connected to the light-emitting diode LED, which are included in a display apparatus according to an embodiment.

Referring to FIG. 4, in an embodiment, a light-emitting diode, for example, a first electrode (e.g., an anode) of the light-emitting diode LED, may be connected to the pixel circuit PC, and a second electrode (e.g., a cathode) of the light-emitting diode LED may be connected to a common voltage line VSL for providing a common power voltage ELVSS. The light-emitting diode LED may emit light with a luminance corresponding to an amount of current supplied from the pixel circuit PC.

The light-emitting diode LED of FIG. 4 may correspond to each of the first to third light-emitting diodes LED1, LED2, and LED3 illustrated above in FIG. 2, and the pixel circuit PC of FIG. 4 may correspond to each of the first to third pixel circuits PC1, PC2, and PC3 illustrated above in FIG. 2.

The pixel circuit PC may control, in response to a data signal, the amount of current flowing from a driving power voltage ELVDD to the common power voltage ELVSS via the light-emitting diode LED. The pixel circuit PC may include a driving transistor M1, a switching transistor M2, a sensing transistor M3, and a storage capacitor Cst.

The driving transistor M1, the switching transistor M2, the sensing transistor M3 may each be an oxide semiconductor thin film transistor including a semiconductor layer including or formed of an oxide semiconductor, or a silicon semiconductor thin film transistor including a semiconductor layer including or formed of polysilicon. Depending on the type of a transistor, a first electrode may be one of a source electrode and a drain electrode, and a second electrode may be the other of the source electrode and the drain electrode.

The first electrode of the driving transistor M1 may be connected to a driving voltage line VDL for providing the driving power voltage ELVDD, and the second electrode may be connected to the first electrode of the light-emitting diode LED. A gate electrode of the driving transistor M1 may be connected to a first node N1. The driving transistor M1 may control, in response to a voltage of the first node N1, the amount of current flowing from the driving power voltage ELVDD to the light-emitting diode LED.

The switching transistor M2 may be a switching transistor. A first electrode of the switching transistor M2 may be connected to a data line DL, and a second electrode thereof may be connected to the first node N1. A gate electrode of the switching transistor M2 may be connected to a scan line SL. The switching transistor M2 is turned on when a scan signal is supplied to the scan line SL, to electrically connect the data line DL and the first node N1 to each other.

The sensing transistor M3 may be an initialization transistor and/or a sensing transistor. A first electrode of the sensing transistor M3 may be connected to a second node N2, and a second electrode thereof may be connected to a sensing line SEL. A gate electrode of the sensing transistor M3 may be connected to a control line CL.

The storage capacitor Cst may be connected between the first node N1 and the second node N2. In an embodiment, for example, a first capacitor electrode of the storage capacitor Cst may be connected to the gate electrode of the driving transistor M1, and a second capacitor electrode of the storage capacitor Cst may be connected to the first electrode of the light-emitting diode LED.

Although FIG. 4 illustrates an embodiment where the driving transistor M1, the switching transistor M2, and the sensing transistor M3 are n-channel metal-oxide-semiconductor (NMOS) transistors, the disclosure is not limited thereto. In an embodiment, for example, at least one selected from the driving transistor M1, the switching transistor M2, and the sensing transistor M3 may be a p-channel metal-oxide-semiconductor (PMOS) transistor.

Although FIG. 4 illustrates an embodiment where the pixel circuit PC includes three transistors, the disclosure is not limited thereto. The pixel circuit PC may include four or more transistors.

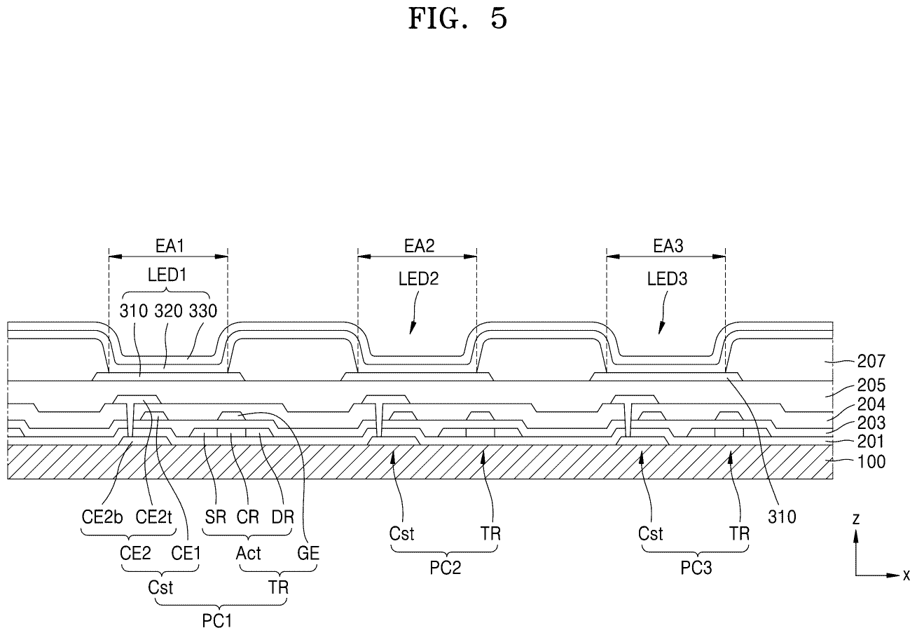

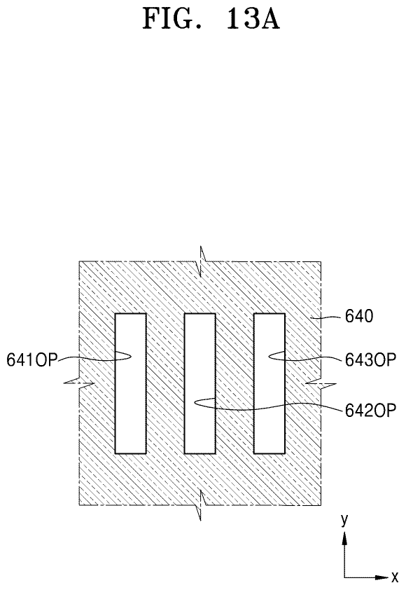

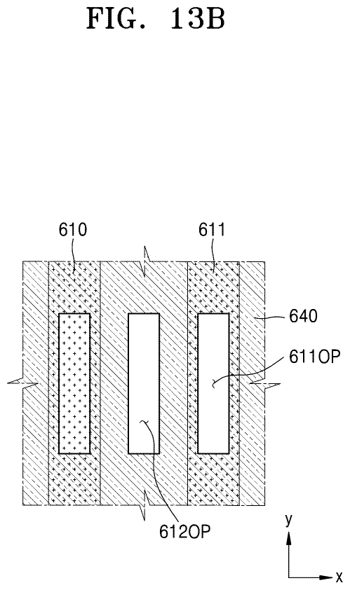

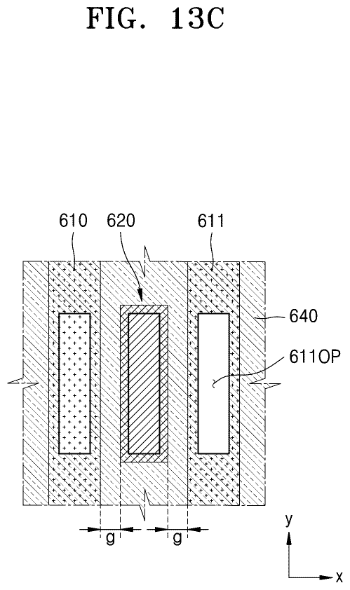

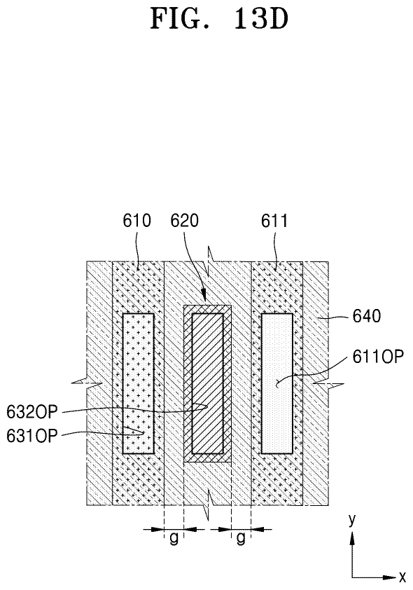

FIGS. 5 to 12 are cross-sectional views showing a method of manufacturing a display apparatus, according to an embodiment. FIG. 13A is a plan view of a color adjustment layer formed by a method of manufacturing a display apparatus, according to an embodiment. FIG. 13B is a plan view showing a process of forming a first color layer on the color adjustment layer. FIG. 13C is a plan view showing a process of forming a second color layer after the first color layer is formed. FIG. 13D is a plan view showing a process of forming a third color layer after the second color layer is formed. In the following description, an embodiment in which the light-emitting diode LED is an organic light-emitting diode will be described.

Referring to FIG. 5, the first to third pixel circuits PC1, PC2, and PC3 are formed on the substrate 100. The substrate 100 may include glass or polymer resin. The substrate 100 may be a glass substrate including SiO₂ as a main ingredient. The glass substrate may be a glass substrate having a thickness of, for example, about 500 micrometers (μm), or an ultra-thin glass substrate having a thickness of, for example, about 30 μm. The substrate 100 including polymer resin may be flexible, foldable, rollable, or bendable. The substrate 100 may have a multilayer structure including a layer including polymer resin described above and an inorganic layer (not shown).

The first to third pixel circuits PC1, PC2, and PC3 may each include a driving transistor, a switching transistor, a sensing transistor, and a storage capacitor, as described above with reference to FIG. 4. FIG. 5 illustrates a transistor TR corresponding to one of the driving transistor, the switching transistor, and the sensing transistor, and the storage capacitor Cst.

In an embodiment, the storage capacitor Cst may include a first capacitor electrode CE1 and a second capacitor electrode CE2, and the second capacitor electrode CE2 may include a first sub-capacitor electrode CE2b and a second sub-capacitor electrode CE2t, which are respectively formed below and above the first capacitor electrode CE1 therebetween.

The first sub-capacitor electrode CE2b may be formed directly on the substrate 100. In an embodiment, for example, the first sub-capacitor electrode CE2b may be in direct contact with an upper surface of the substrate 100. The first sub-capacitor electrode CE2b may include a conductive metal, such as aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and/or copper (Cu). Although not illustrated, the driving voltage line, the common voltage line, and/or the data line, which are described with reference to FIG. 4, may be formed together with the first sub-capacitor electrode CE2b in a same process.

Then, a buffer layer 201 may be formed. The buffer layer 201 may be disposed on the first sub-capacitor electrode CE2b, and may include an inorganic insulating material. The buffer layer 201 may include an inorganic insulating material, such as a silicon nitride, a silicon oxide, and/or a silicon oxynitride, and have a single layer or multilayer structure, each layer therein including at least one selected from the materials described above.

Next, a semiconductor layer Act of the transistor TR may be formed. The semiconductor layer Act may include an oxide-based semiconductor material such as IGZO, or a silicon-based conductor material such as polysilicon.

A gate insulating layer 203 may be formed on the semiconductor layer Act. The gate insulating layer 203 may include an inorganic insulating material, such as a silicon nitride, a silicon oxide, and/or a silicon oxynitride, and have a single layer or multilayer structure, each layer therein including at least one selected from the materials described above.

A gate electrode GE may be formed on the gate insulating layer 203 and overlap a part of the semiconductor layer Act. The gate electrode GE may overlap a channel region CR of the semiconductor layer Act, and the semiconductor layer Act may include the channel region CR, and a source region SR and a drain region DR arranged in the opposite sides of the channel region CR.

The first capacitor electrode CE1 may be formed in (or directly on) a same layer as the gate electrode GE, and may include a same material as the gate electrode GE. The first capacitor electrode CE1 and the gate electrode GE may be formed in the same process. The first capacitor electrode CE1 and the gate electrode GE may each include a conductive metal, such as Al, Pt, Pd, Ag, Mg, Au, Ni, Nd, Ir, Cr, Ni, Ca, Mo, Ti, W, and/or Cu. Alternatively, the first capacitor electrode CE1 and the gate electrode GE may each include a transparent conductive oxide layer such as ITO disposed on the metal layer described above.

An interlayer insulating layer 204 may be formed on the first capacitor electrode CE1 and the gate electrode GE. The interlayer insulating layer 204 may include an inorganic insulating material, such as a silicon nitride, a silicon oxide, and/or a silicon oxynitride, and have a single layer or multilayer structure, each layer therein including at least one selected from the material described above.

The second sub-capacitor electrode CE2t may be formed on the interlayer insulating layer 204. The second sub-capacitor electrode CE2t may be electrically connected to the first sub-capacitor electrode CE2b via a contact hole defined or formed through insulating layer(s) provided between the first sub-capacitor electrode CE2b and the second sub-capacitor electrode CE2t. In an embodiment, for example, the second sub-capacitor electrode CE2t may be connected to the first sub-capacitor electrode CE2b via a contact hole defined through the buffer layer 201, the gate insulating layer 203, and the interlayer insulating layer 204.

A via insulating layer 205 may be formed on the first to third pixel circuits PC1, PC2, and PC3. The via insulating layer 205 may include an inorganic insulating material and/or an organic insulating material. In an embodiment, for example, the via insulating layer 205 may include an organic insulating material, such as acryl, benzocyclobutene (BCB), polyimide (PI), hexamethyldisiloxane (HMDSO), or the like.

The first to third pixel circuits PC1, PC2, and PC3 disposed on the substrate 100 may each include the transistor TR and the storage capacitor Cst, both having the structure as described above, and may be electrically connected to a first electrode 310 of a corresponding light-emitting diode.

The first electrode 310 may be spaced apart from each other on the via insulating layer 205. The first electrode 310 may include a reflective film including Ag, Mg, Al, Pt, Pd, Au, Ni, Nd, Ir, Cr, or a compound thereof. The first electrode 310 may include a reflective film including at least one selected from the materials described above, and a transparent conductive film disposed above or/and below the reflective film. The transparent conductive film may include an indium tin oxide (ITO), an indium zinc oxide (IZO), a zinc oxide (ZnO), an indium oxide (In₂O₃), an indium gallium oxide (IGO), an aluminum zinc oxide (AZO), or the like. In an embodiment, the first electrode 310 may have a three layer structure of ITO layer/Ag layer/ITO layer.

A bank layer 207 may include openings each overlapping the first electrode 310 of each of the first to third light-emitting diodes LED1, LED2, and LED3. The bank layer 207 may cover the edge of the first electrode 310 and expose the central portion of the first electrode 310 through each opening. The openings of the bank layer 207 may respectively define first to third emission areas EA1, EA2, and EA3 of the first to third light-emitting diodes LED1, LED2, and LED3.

The bank layer 207 may include an organic insulating material. In an embodiment, for example, the bank layer 207 may include an organic insulating material, such as acryl, BCB, PI, HMDSO, or the like.

An emission layer 320 may be formed on the bank layer 207, and a second electrode 330 may be formed on the emission layer 320. The emission layer 320 may include a polymer or low molecular weight organic material for emitting blue light. The emission layer 320 may be formed to entirely cover the substrate 100. The second electrode 330 may also be formed to entirely cover the substrate 100.

The second electrode 330 may be a semi-transmissive or transmissive electrode. The second electrode 330 may be a semi-transmissive electrode including an ultra-thin film metal including Mg, Ag, Al, Pt, Pd, Au, Ni, Nd, Ir, Cr, or a compound thereof. The second electrode 330 may include a transparent conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO).

The first electrode 310, the emission layer 320 and the second electrode 330, which overlap one another through the openings of the bank layer 207, may form a light-emitting diode for emitting blue light. The light-emitting diodes are spaced apart from each other, as shown FIG. 5 in which the first to third light-emitting diodes LED1, LED2, and LED3 are illustrated. The openings of the bank layer 207 may each define the emission area of each light-emitting diode. In an embodiment, for example, the opening of the bank layer 207 corresponding to the first light-emitting diode LED1 may define the first emission area EA1, the opening of the bank layer 207 corresponding to the second light-emitting diode LED2 may define the second emission area EA2, and the opening of the bank layer 207 corresponding to the third light-emitting diode LED3 may define the third emission area EA3. The width of each of the first to third the emission areas EA1, EA2, and EA3 corresponds to the width of each of the openings of the bank layer 207.

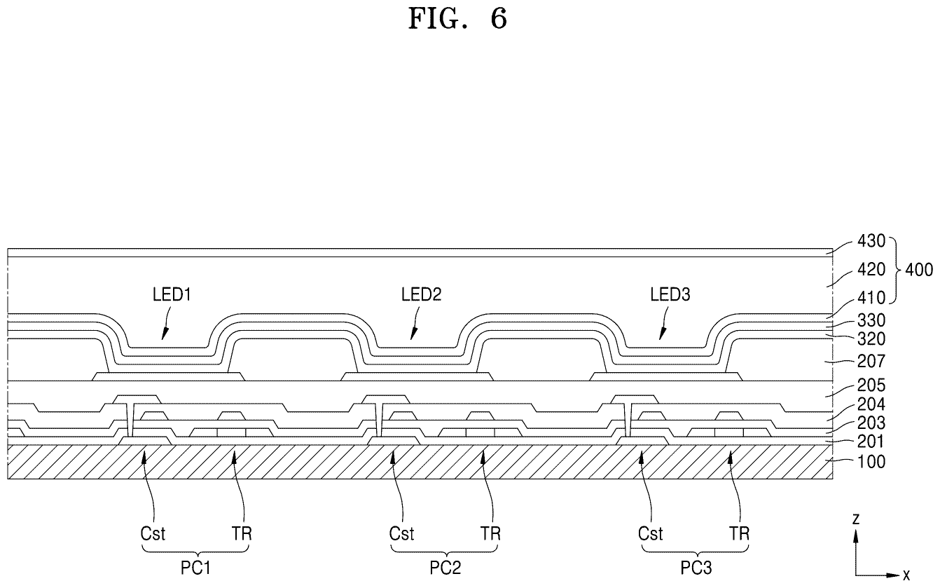

Referring to FIG. 6, the encapsulation layer 400 is formed on the first to third light-emitting diodes LED1, LED2, and LED3. The encapsulation layer 400 may include at least one inorganic encapsulation layer and at least one organic encapsulation layer. In an embodiment, the encapsulation layer 400 may include first and second inorganic encapsulation layers 410 and 430 and an organic encapsulation layer 420 therebetween.

The first and second inorganic encapsulation layers 410 and 430 may each include one or more inorganic insulating materials. The inorganic insulating material may include an aluminum oxide, a titanium oxide, a tantalum oxide, a hafnium oxide, a zinc oxide, a silicon oxide, a silicon nitride, and/or a silicon oxynitride.

The organic encapsulation layer 420 may include a polymer-based material. The polymer-based material may include acrylic resin, epoxy-based resin, PI and polyethylene, or the like. In an embodiment, for example, the organic encapsulation layer 420 may include acrylic resin, for example, polymethylmethacrylate, polyacryl acid, or the like. The organic encapsulation layer 420 may be formed by curing a monomer or coating a polymer.

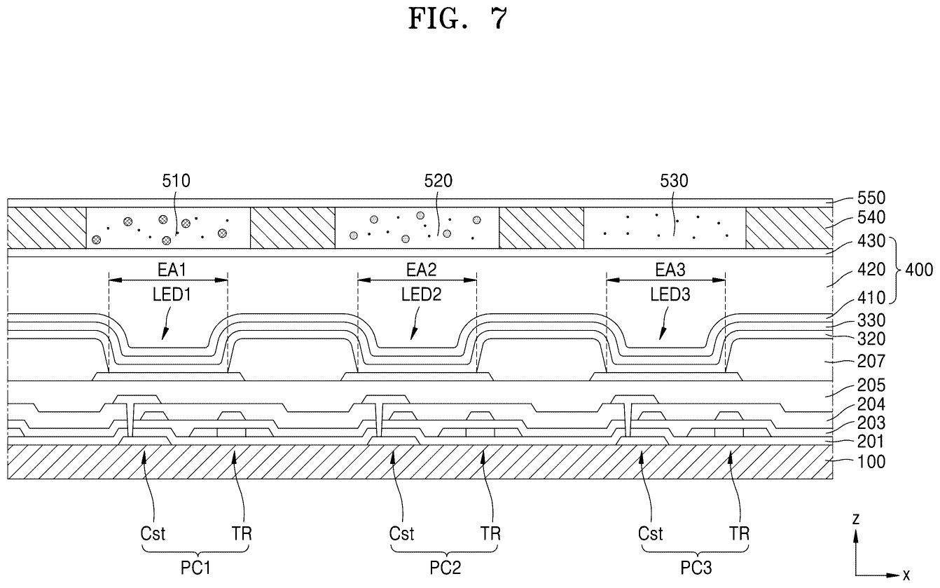

Referring to FIG. 7, a light blocking partition wall 540 may be formed on the encapsulation layer 400. The light blocking partition wall 540 may be formed to surround the emission area, for example, each of the first to third the emission areas EA1, EA2, and EA3, and the light blocking partition wall 540 may have a net structure on a plane (on an x-y plane).

The light blocking partition wall 540 may include a colored insulating material, for example, a black color. In an embodiment, for example, the light blocking partition wall 540 may include a PI-based binder, and a pigment in which red, green, and blue are mixed. Alternatively, the light blocking partition wall 540 may include cardo-based binder resin and a mixture of a lactam-based black pigment and a blue pigment. Alternatively, the light blocking partition wall 540 may include carbon black. The light blocking partition wall 540 may effectively prevent converted and scattered light from traveling toward other areas in the first and second color conversion portions 510 and 520 and the transmitting portion 530 to be described below. Furthermore, the light blocking partition wall 540, together with the color filters to be described below, may effectively prevent the reflection of external light, thereby improving the contrast of a display apparatus.

After forming the light blocking partition wall 540, the first color conversion portion 510, the second color conversion portion 520, and the transmitting portion 530 are each formed. The materials of the first color conversion portion 510, the second color conversion portion 520, and the transmitting portion 530 may be the same as those described above with reference to FIG. 3. The first color conversion portion 510, the second color conversion portion 520, and the transmitting portion 530 may each be formed by an inkjet method.

An insulating layer 550 may entirely cover the first color conversion portion 510, the second color conversion portion 520, the transmitting portion 530, and the light blocking partition wall 540. The insulating layer 550, as a kind of a barrier layer, may protect the elements thereunder, for example, the first color conversion portion 510, the second color conversion portion 520, the transmitting portion 530, and the light blocking partition wall 540, from external foreign materials. The insulating layer 550 may include an inorganic insulating material.

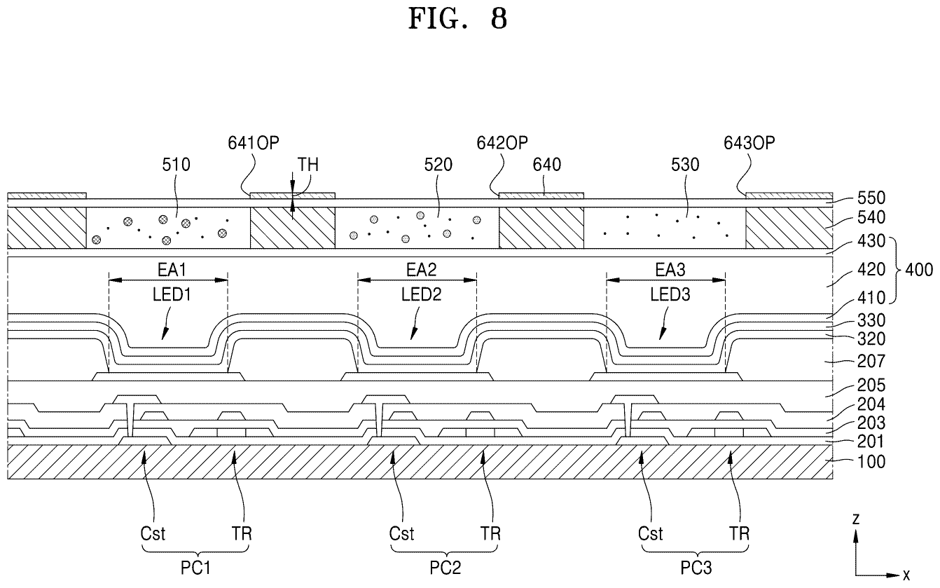

Then, as illustrated in FIGS. 8 and 13A, a color adjustment layer 640 may be formed. The color adjustment layer 640 may be formed by forming and patterning a material layer (not shown) having a fourth color. The fourth color may be different from the first to third colors described above. The color adjustment layer 640 may be disposed on the light blocking partition wall 540 to correspond to the light blocking partition wall 540. The color adjustment layer 640 may be disposed overlapping the bank layer 207.

The color adjustment layer 640 may define a first opening 641OP corresponding to the first emission area EA1, a second opening 642OP corresponding to the second emission area EA2, and a third opening 643OP corresponding to the third emission area EA3. The size of the first opening 641OP may be greater than the size of the first emission area EA1, the size of the second opening 642OP may be greater than the size of the second emission area EA2, and the size of the third opening 643OP may be greater than the size of the third emission area EA3. However, the disclosure may not be limited thereto. In an embodiment, for example, the size of the first opening 641OP may be the same as the size of the first emission area EA1, the size of the second opening 642OP may be the same as the size of the second emission area EA2, and the size of the third opening 643OP may be the same as the size of the third emission area EA3. The light emitted from the first to third light-emitting diodes LED1, LED2, and LED3 may respectively pass and travel through the first opening 641OP, the second opening 642OP and the third opening 643OP of the color adjustment layer 640.

In the subsequent process, at least a part of the first color filter 610 may be provided in the first opening 641OP, at least a part of the second color filter 620 may be provided in the second opening 642OP, and at least a part of the third color filter 630 may be provided in the third opening 643OP.

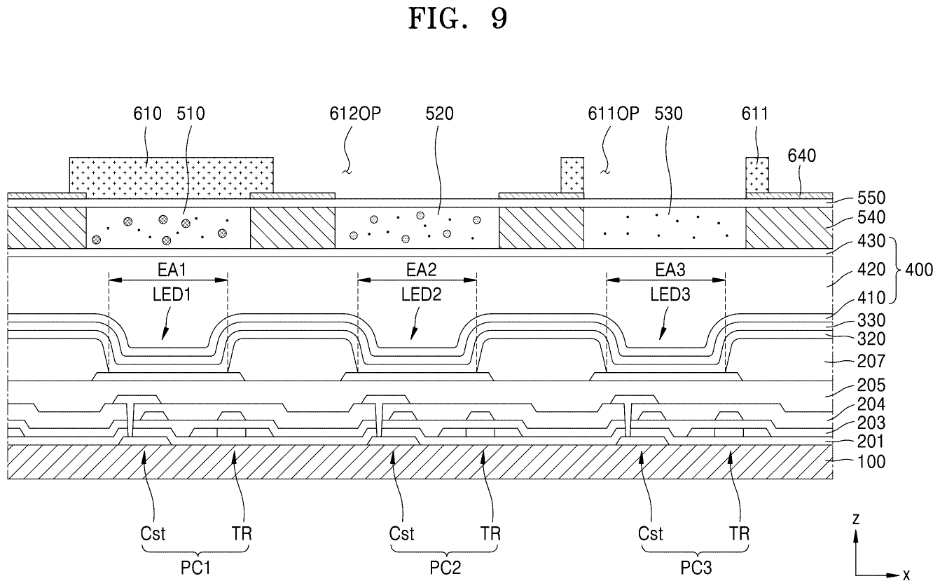

Referring to FIGS. 9 and 13B, a material layer (not shown) having a first color may be formed on the insulating layer 550 and then patterned, and thus, the first color layer including the first color filter 610 and a first dummy color filter 611 may be formed.

The first color filter 610 may be disposed on the first emission area EA1 to overlap the first emission area EA1. The first color filter 610 may have a size greater than that of the first emission area EA1 to at least cover the first emission area EA1. In an embodiment, for example, the inner portion (or the central portion) of the first color filter 610 may overlap and cover the first emission area EA1 and the first color conversion portion 510 that are located directly under the first color filter 610, and the outer portion (or the end portion) of the first color filter 610 may overlap the light blocking partition wall 540 that surrounds the first color conversion portion 510. In an embodiment, at least a part of the first color filter 610 may be disposed or filled in the first opening OP1 of FIG. 8 of the color adjustment layer 640, and the outer portion (or the end portion) of the first color filter 610 may overlap the end portion of the color adjustment layer 640 defining the first opening 641OP.

In the process of forming the first color filter 610, the first dummy color filter 611 may be formed. The first dummy color filter 611 may have a same color as the first color filter 610, and may include a same material as the first color filter 610. The first color filter 610 and the first dummy color filter 611 may each include a material having the first color, for example, a red pigment or dye. In an embodiment, the first dummy color filter 611 may at least partially overlap the end portion of the color adjustment layer 640 defining the third opening 643OP.

The first dummy color filter 611 may surround or define a first opening portion 611OP that corresponds to the third emission area EA3. The first dummy color filter 611 may overlap the light blocking partition wall 540 that surrounds the transmitting portion 530. As illustrated in FIG. 13B, in a plan view, the first opening portion 611OP may be entirely surrounded by the first dummy color filter 611. A second opening portion 612OP may be located between the first color filter 610 corresponding to the first emission area EA1 in a plan view and the first dummy color filter 611 surrounding the third emission area EA3 in a plan view. In other words, the first color layer is present at a position corresponding to the first emission area EA1, and in a non-emission area between the adjacent emission areas (or a light blocking area where the light blocking partition wall 540 is located), but not present at positions corresponding to the second and third emission areas EA2 and EA3.

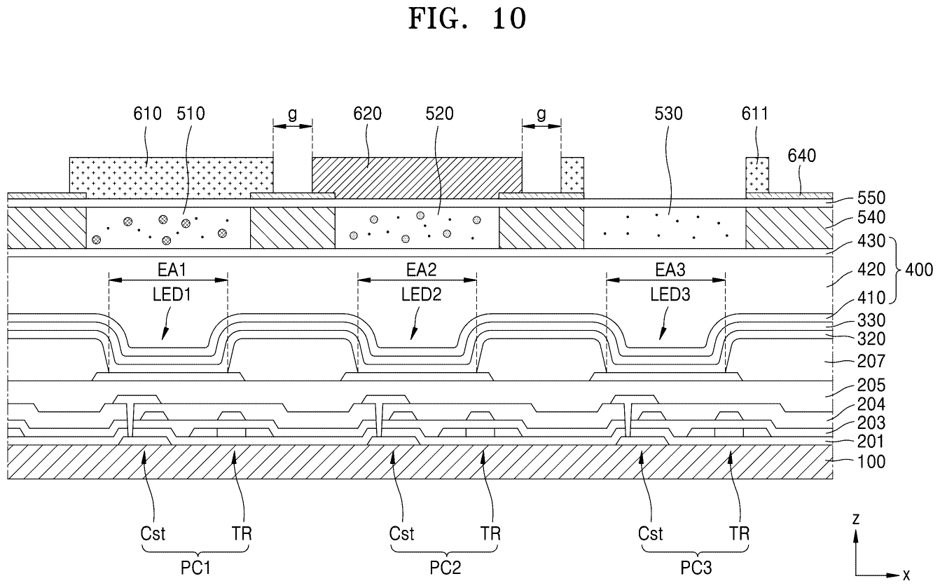

Next, referring to FIG. 10, a material layer (not shown) having a second color is formed on the structure described with reference to FIG. 9 and then patterned to form a second color layer including the second color filter 620. In an embodiment, the second color layer, as illustrated in FIG. 13C, may include the second color filter 620 that is in an isolated shape (or an island shape). The second color filter 620 may include a material having the second color, for example, a green pigment or dye.

The second color filter 620 may be formed on the second emission area EA2 to overlap the second emission area EA2. The second color filter 620 may have a size greater than that of the second emission area EA2 to at least cover the second emission area EA2. The inner portion (or the central portion) of the second color filter 620 may overlap and cover the second emission area EA2 and the second color conversion portion 520 directly under the second color filter 620, and the outer portion (or the end portion) of the second color filter 620 may overlap the light blocking partition wall 540 that surrounds the second color conversion portion 520. In an embodiment, at least a part of the second color filter 620 may be disposed or filled in the second opening OP2 of FIG. 8 of the color adjustment layer 640, and the outer portion (or the end portion) of the second color filter 620 may overlap the end portion of the color adjustment layer 640 defining the second opening 642OP.

A first end portion of the second color filter 620 may be arranged adjacent to a first end portion of the first color filter 610, but both are not in contact with each other. In other words, the first end portion of the first color filter 610 and the first end portion of the second color filter 620 may be adjacent to each other while being spaced apart from each other with a gap g therebetween.

Similarly, a second end portion of the second color filter 620 may be arranged adjacent to a first end portion of the first dummy color filter 611, but both are not in contact with each other. In other words, the second end portion of the second color filter 620 and the first end portion of the first dummy color filter 611 may be adjacent to each other and also spaced apart from each other while maintaining the gap g therebetween.

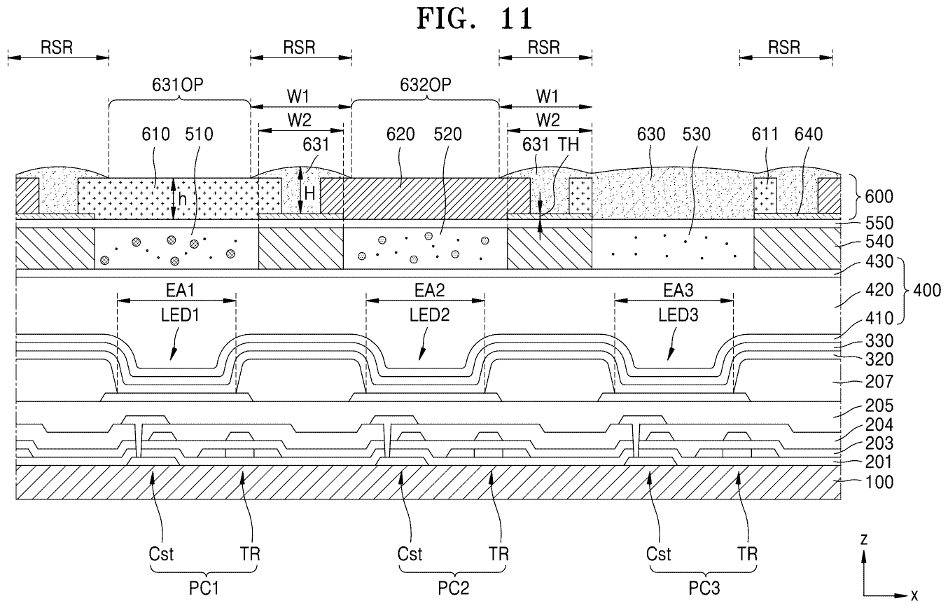

Then, as illustrated in FIG. 11, a material layer (not shown) having a third color is formed and then patterned to form a third color layer including the third color filter 630. The third color filter 630 may include a material having the third color, for example, a blue pigment or dye. The overlapping structure of the first to third color layers described with reference to FIGS. 9 to 11 may form or collectively define the color layer 600.

The third color filter 630 may be formed on the third emission area EA3 to correspond to the third emission area EA3. The third color filter 630 may have a size greater than that of the third emission area EA3 to at least cover the third emission area EA3. In an embodiment, at least a part of the third color filter 630 may be buried in the third opening OP3 of FIG. 8 of the color adjustment layer 640.

The third color filter 630 may extend to the non-emission area between the adjacent emission areas (or the light blocking area where the light blocking partition wall 540 is located). In an embodiment, as illustrated in FIGS. 11 and 13D, may define a third opening portion 631OP overlapping the first emission area EA1, a fourth opening portion 632OP overlapping the second emission area EA2, and the third color filter 630 overlapping the third emission area EA3. A third color material 631 forming the third color layer may be present in the non-emission area (or the area where the light blocking partition wall 540 is located). The third color material 631 may have the same third color as the third color filter 630.

In the non-emission area between the first emission area EA1 and the second emission area EA2 (or the area where the light blocking partition wall 540 is located), the first end portion of the first color filter 610 and the first end portion of the second color filter 620 may be spaced apart from each other with the certain gap g of FIG. 10), but may overlap the light blocking partition wall 540. The third color material 631 may overlap the first end portion of the first color filter 610 and the first end portion of the second color filter 620, which are spaced apart from each other, in the non-emission area (or the area where the light blocking partition wall 540 is located). A part of the third color material 631 may at least partially fill the gap g of FIG. 10. The third color material 631 may be in direct contact with a side surface of the first end portion of the first color filter 610 and a side surface of the first end portion of the second color filter 620, facing each other while maintaining the gap g of FIG. 10 therebetween. The third color material 631 may be in direct contact with a part of the upper surface of the first color filter 610 connected to the side surface of the first color filter 610 described above and a part of the upper surface of the second color filter 620 connected to the side surface of the second color filter 620 described above. The upper surface of the third color material 631 in the non-emission area between the first emission area EA1 and the second emission area EA2 may have a cross-sectional structure having an approximately T shape with a convex upper surface.

The structure of the first end portion of the first color filter 610 and the first end portion of the second color filter 620, which are spaced apart from each other, and the third color material 631 overlapping the first end portions of the first and second color filters 610 and 620 corresponds to the structure of a light blocking area RSR of the color layer 600. The width of the light blocking area RSR of the color layer 600 corresponds to a width W1 of the third color material 631 described above.

The structure in the non-emission area between the second emission area EA2 and the third emission area EA3 (or the area where the light blocking partition wall 540 is located) may have substantially the same structure as the structure in the non-emission area between the first emission area EA1 and the second emission area EA2 described above (or the area where the light blocking partition wall 540 is located between the first color conversion portion 510 and the second color conversion portion 520).

In the non-emission area between the second emission area EA2 and the third emission area EA3 (or the area where the light blocking partition wall 540 is located), the second end portion of the second color filter 620 and the first end portion of the first dummy color filter 611 may be spaced apart from each other while forming the certain gap g of FIG. 10, and may overlap the light blocking partition wall 540. The third color material 631 may overlap the second end portion of the second color filter 620 and the first end portion of the first dummy color filter 611, which are spaced apart from each other, in the non-emission area (or the area where the light blocking partition wall 540 is located). A part of the third color material 631 may at least partially fill the gap g of FIG. 10. The third color material 631 may be in direct contact with the side surface of the second end portion of the second color filter 620 and the side surface of the first end portion of the first dummy color filter 611, facing each other while maintaining the gap g of FIG. 10. The third color material 631 may be in direct contact with the part of the upper surface of the second color filter 620 connected to the side surface of the second color filter 620 described above and at least the part of the upper surface of the first dummy color filter 611 connected to the side surface of the first dummy color filter 611 described above. The upper surface of the third color material 631 in the non-emission area between the second emission area EA2 and the third emission area EA3 may have a cross-sectional structure having an approximately T shape with a convex upper surface, as described above.

The width W1 of the third color material 631 in the light blocking area RSR may be greater than a width W2 of the light blocking partition wall 540 located directly thereunder. In another embodiment, the width W1 of the third color material 631 in the light blocking area RSR may be the same as the width W2 of the light blocking partition wall 540. Alternatively, the width W1 of the third color material 631 in the light blocking area RSR may be less than the width W2 of the light blocking partition wall 540.

In the structure of the light blocking area RSR of the color layer 600, two color materials selected from different color materials of the first color, the second color, and the third color may be covered by the other color material. In an embodiment, for example, in the light blocking area RSR between the first and second emission areas EA1 and EA2, the first color filter 610 of the first color and the second color filter 620 of the second color are spaced apart from each other and covered by the third color material 631 of the third color. In such an embodiment, in the light blocking area RSR between the second and third emission areas EA2 and EA3, the first dummy color filter 611 of the first color and the second color filter 620 of the second color are spaced apart from each other and covered by the third color material 631 of the third color.

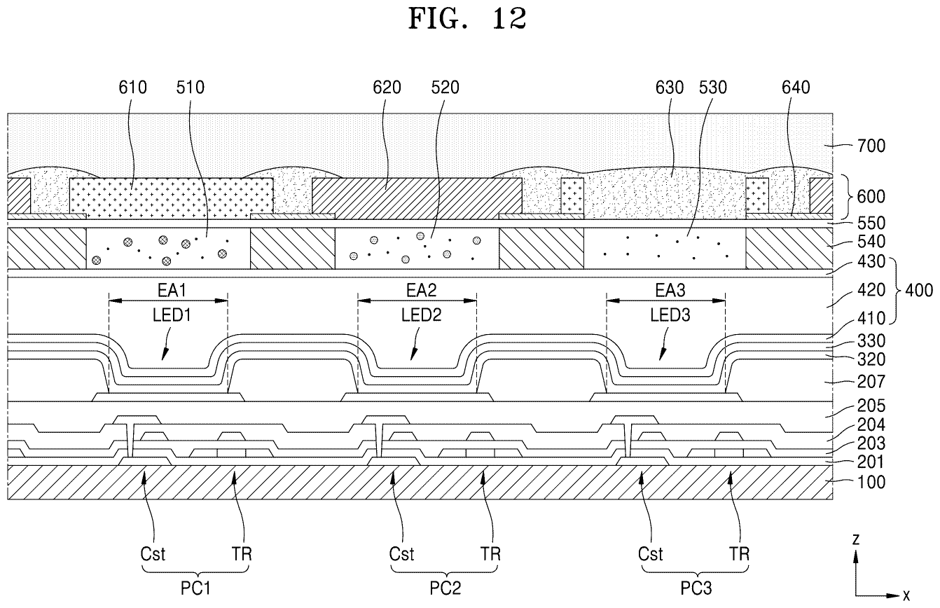

As a comparative example, when different color material layers of a first color, a second color, and a third color are stacked in the light blocking area RSR, the top surface of the three color material layers overlapping one another in the light blocking area RSR has a curved surface having a relatively large curvature, compared with the embodiment illustrated in FIG. 11. The curved surface of the color layer 600 in the light blocking area RSR may cause unevenness in the upper surface of an overcoat layer 700 (see FIG. 12) to be described below, so that diffuse reflection of the external light incident on the display apparatus is induced. According to one or more embodiments, the third color material overlaps the first and second color materials spaced apart from each other, and thus, the external light diffuse reflection phenomenon described above may be reduced while maintaining functions, such as light shielding, mixed color, external light absorption, or the like.

In the light blocking area RSR, the width W1 of the third color material 631 may be greater than a height H of the third color material 631. For example, a ratio of the height to the width W1 of the third color material 631 (H/W1) may be about 0.19 or less. In other words, the height H of the third color material 631 may be less than about 0.19 times the width W1 of the third color material 631. Here, H denotes the greatest height of the third color filter 630 in the light blocking area. When the condition (H/W1<0.19) described above is satisfied, the diffuse reflection may be reduced. As an experimental example, in a display apparatus having the structure according to one or more embodiments, compared with the display apparatus according to the comparative example, the diffuse reflection may be reduced by about 48%.

The height H of the third color material 631 may be greater than the height H of the central portion of the first color filter 610. The greater a difference between the height H of the third color material 631 and the height H of the central portion of the first color filter 610, the greater the diffuse reflection by the curved surface of the color layer 600 in the light blocking area RSR. Thus, the difference between the height H of the third color material 631 and the height H of the central portion of the first color filter 610 may be about 2.5 μm or less. In an embodiment, the height H of the third color material 631 may be about 6.5 μm, and the height H of the central portion of the first color filter 610 may be about 3.5 μm or greater.

The third color material 631 of the third color located on the top layer in the light blocking area RSR may include a material having a relatively lower reflectivity than that of a color material of a different color. In an embodiment, for example, the reflectivity of the third color material 631 in a wavelength band of about 460 nanometers (nm) to about 550 nm may be lower than the reflectively of the first and second color materials. In this case, by forming the third color layer including the third color material 631 at the end, the top layer of the color layer 600 has the third color in the light blocking area RSR so that the reflection of external light may be reduced.

According to an embodiment, as described with reference to FIGS. 9 to 11, and FIGS. 13B to 13D, the color layers are formed in the order of the first color layer including the first color filter 610 of red, the second color layer including the second color filter 620 of green, and the third color layer including the third color filter 630 of blue (the forming order of the first color layer and the second color layer may be changed), but the disclosure is not limited thereto. In another embodiment, when the second color material have a reflectivity lower than the reflectivity of the first and third color materials, the light blocking area RSR of the color layer 600 may have a structure in which the first color material and the third color material that are spaced apart from each other with a gap is covered by the second color material. In this case, after forming the first color layer including the first color material and the third color layer including the third color material, the second color layer including the second color material may be formed.

The refractive index of the color material located in the top layer in the light blocking area RSR may be less than the refractive indexes of other color materials. Referring to FIG. 11, in an embodiment, the refractive index of the third color material 631 may be less than the refractive indexes of the first color filter 610, the first dummy color filter 611, and the second color filter 620. Accordingly, the reflection of external light described above may be effectively reduced. In an embodiment, the refractive index of the third color material 631 may be in a range of about 1.4 to about 1.8 (e.g., in a range of about 1.5 to about 1.6).

According to an embodiment, as described with reference to FIGS. 9 to 11, and FIGS. 13B to 13D, the color layer 600 may have a structure in which the third color material overlaps the first and second color materials spaced apart from each other with the gap g of FIG. 10, but the disclosure is not limited thereto. In another embodiment, the first and second color material may be in contact with each other without a gap, and the third color material may overlap the first and second color materials. In such an embodiment, the third color material 631 and the color adjustment layer 640 may not be in direct contact with each other.

Referring to FIG. 11, the color adjustment layer 640 may be disposed on the light blocking area RSR of the color layer 600. The width of the color adjustment layer 640 may be the same as the width W2 of the light blocking partition wall 540 disposed thereunder. In another embodiment, the width of the color adjustment layer 640 may be less than the width W2 of the light blocking partition wall 540. Alternatively, the width of the color adjustment layer 640 may be greater than the width W2 of the light blocking partition wall 540. In an embodiment, the color adjustment layer 640 may overlap the third color material 631, and the width of the color adjustment layer 640 may be the same or greater than the width W1 of the third color material 631.

According to one or more embodiments, the color adjustment layer 640 may include a fourth color material of the fourth color different from the first color of the first color filter 610, the second color of the second color filter 620, and the third color of the third color material 631. In an embodiment, for example, the color adjustment layer 640 may include a yellow pigment or dye.

As a comparative example, in a display apparatus in which the third color material is disposed on the first color material and the second color material and no color adjustment layer is provided, reflection color coordinates may move in a direction toward the third color of the third color material 631. For example, in a case where the third color of the third color material is blue, the reflection color of the display apparatus may be changed to be somewhat blue, that is, bluish. In a case where other optical film, for example, an anti-reflection (AR) film, is disposed on the overcoat layer 700 of FIG. 12, the reflection color of a display apparatus may move toward further bluish.

According to one or more embodiments, the color adjustment layer 640 is provided to overlap the third color material 631 and includes the fourth color material of the fourth color different from the third color, unintended or undesired movement of the reflection color coordinates may be effectively prevented. In an embodiment, for example, where the third color of the third color material 631 is blue, the fourth color of the color adjustment layer 640 is yellow, and thus, the reflection color of a display apparatus may be effectively prevented from being changed to be bluish.

In an embodiment, as the color adjustment layer 640 includes the fourth color material of the fourth color different from the first to third colors and is arranged in the light blocking area RSR, the generation of a mixed color because the light emitted from a light-emitting diode of any one pixel and passing through the color converting-transmitting layer 500 travels toward an adjacent pixel may be effectively prevented and the optical density in a non-emission portion may be increased.

In an embodiment, a height TH of the color adjustment layer 640 may be less than the height H of the central portion of the first color filter 610, the height of the second color filter 620, and the height H of the third color material 631. The height TH of the color adjustment layer 640 may be about 1 μm or less. As the height TH of the color adjustment layer 640 is about 1 μm or less, a step formed by the color adjustment layer 640 may be reduced so that diffuse reflection due to the curved surface in the light blocking area RSR may be reduced.

Referring to FIG. 11, like the lower surface of the first color filter 610, the lower surface of the second color filter 620, and the lower surface of the third color filter 630, the lower surface of the color adjustment layer 640 may be in direct contact with the insulating layer 550 disposed thereunder.

Next, as illustrated in FIG. 12, the overcoat layer 700 is formed. The lower surface of the overcoat layer 700 facing the color layer 600 may include a concave and/or convex surface corresponding to the upper surface of the color layer 600. In an embodiment, for example, the lower surface of the overcoat layer 700 may include a concave surface corresponding to the convex upper surface of the third color material 631.

The overcoat layer 700 may include a light-transmissive organic material such as acryl-based resin. The upper surface of the overcoat layer 700 including an organic material may include a relatively flat surface, the flatness of the upper surface of the overcoat layer 700 may be greater than that of the lower surface of the overcoat layer 700.

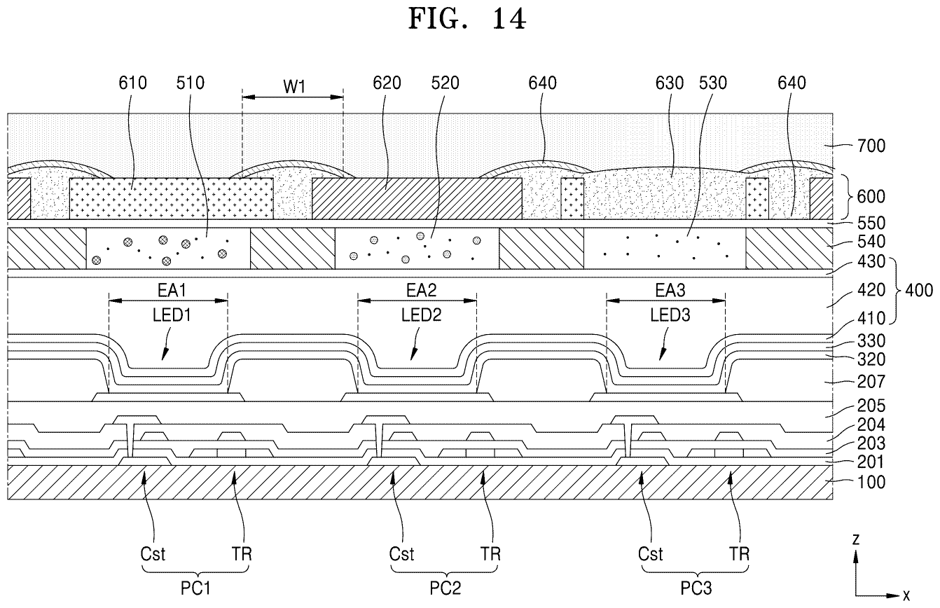

FIG. 14 is a schematic cross-sectional view of a display apparatus according to an embodiment. In FIG. 14, like reference numerals as those of FIG. 12 refer to the same elements, and any repetitive detailed descriptions thereof will be omitted.

Referring to FIG. 14, the color adjustment layer 640 may be disposed between the color layer 600 and the overcoat layer 700. The color adjustment layer 640 may be formed after all of the first color layer, the second color layer, and the third color layer are formed.

The third color material 631 may be arranged to cover the first end portion of the first color filter 610 and the first end portion of the second color filter 620, and the color adjustment layer 640 may be disposed on the third color material 631. The color adjustment layer 640 may cover at least a part of the third color material 631. In an embodiment, as illustrated in FIG. 14, the color adjustment layer 640 may completely cover the upper surface of the third color material 631. The color adjustment layer 640 may be in direct contact with the third color material 631.

According to one or more embodiments, the color layer 600, which includes the first color filter 610, the second color filter 620, the third color material 631 that covers the first end portions of the first and second color filters 610 and 620, and the color adjustment layer 640 with a low height, may not only reduce the reflection of external light, but also effectively prevent a mixed color and further a reflection color from being biased to a specific color. In such embodiments, a degree of color correction may be adjusted by adjusting not only the height of the color adjustment layer 640, but also a solid content included in the fourth color material of the color adjustment layer 640 and/or the size of the opening of the color adjustment layer 640 and the like.

The structure of the color layer 600, the color adjustment layer 640, and the overcoat layer 700 described with reference to FIGS. 8 to 12 may be applied to a case in which the display apparatus includes the color converting-transmitting layer 500, as illustrated in FIGS. 2 and 12, but the disclosure is not limited thereto. In another embodiment, the light-emitting diode layer of the display apparatus may include red, green, and blue light-emitting diodes, and in this case, the color converting-transmitting layer 500 may be omitted. In other words, when the light-emitting diodes emit light of different colors, the color converting-transmitting layer 500 may be omitted. As described above, the display apparatus according to another embodiment may include the color layer 600 and the color adjustment layer 640 having the structure as described with reference to FIGS. 8 to 12, to reduce the reflection of external light and adjust the reflection color.

According to one or more embodiments, the reflection of external light due to the unevenness of the upper surface of the color layer in the light blocking area may be effectively prevented, or a high quality image may be displayed by adjusting reflection color coordinates.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a first light-emitting diode disposed in a first emission area;
a second light-emitting diode disposed in a second emission area;
an encapsulation layer disposed on the first light-emitting diode and the second light-emitting diode, wherein the encapsulation layer comprises at least one inorganic encapsulation layer and at least one organic encapsulation layer;
a color converting-transmitting layer disposed on the encapsulation layer, wherein the color converting-transmitting layer comprises a color conversion portion and a light blocking partition wall surrounding the color conversion portion, wherein the color conversion portion converts light emitted from one of the first light-emitting diode and the second light-emitting diode into light of a different color;
a first color filter disposed on the color converting-transmitting layer corresponding to the first emission area;
a second color filter disposed on the color converting-transmitting layer and corresponding to the second emission area;
a third color material covering a first end portion of the first color filter and a first end portion of the second color filter; and
a color adjustment layer disposed on the color converting-transmitting layer corresponding to the light blocking partition wall.

2. The display apparatus of claim 1, wherein a height of the color adjustment layer is less than a height of a central portion of the first color filter and a height of a central portion of the second color filter.

3. The display apparatus of claim 1, wherein a height of the color adjustment layer is about 1 μm or less.

4. The display apparatus of claim 1, wherein the color adjustment layer comprises a first color material of the first color filter, a second color material of the second color filter, and a fourth color material having a color different from the third color material.

5. The display apparatus of claim 4, wherein the color adjustment layer comprises a yellow pigment or dye.

6. The display apparatus of claim 1, wherein in a visible light wavelength band of about 380 nm to about 780 nm, a reflectivity of the third color material is less than a reflectivity of each of a first color material of the first color filter and a second color material of the second color filter.

7. The display apparatus of claim 1, wherein the color adjustment layer overlaps at least a part of the third color material.

8. The display apparatus of claim 1, further comprising:
an insulating layer disposed on the color converting-transmitting layer,
wherein a lower surface of the first color filter, a lower surface of the second color filter, and a lower surface of the color adjustment layer are in direct contact with the insulating layer.

9. The display apparatus of claim 1, wherein a first end portion of the first color filter and a first end portion of the second color filter are spaced apart from each other with a gap therebetween while overlapping the light blocking partition wall, and a part of the third color material is at least partially disposed in the gap.

10. The display apparatus of claim 1, wherein the color adjustment layer overlaps at least a part of the third color material.

11. The display apparatus of claim 1, further comprising:
an overcoat layer disposed on the first color filter and the second color filter,
wherein a lower surface of the overcoat layer includes a concave surface corresponding to a convex surface included in an upper surface of the third color material.

12. The display apparatus of claim 11, wherein the color adjustment layer is disposed between the third color material and the overcoat layer.

13. The display apparatus of claim 1, wherein the color conversion portion comprises quantum dots.

14. A display apparatus comprising:
a light-emitting diode layer comprising a first light-emitting diode disposed in a first emission area, a second light-emitting diode disposed in a second emission area, and a third light-emitting diode disposed in a third emission area;
an encapsulation layer disposed on the light-emitting diode layer, wherein the encapsulation layer comprises at least one inorganic encapsulation layer and at least one organic encapsulation layer;
a first color filter disposed on the encapsulation layer and corresponding to the first emission area;
a second color filter disposed on the encapsulation layer and corresponding to the second emission area;
a third color filter disposed on the encapsulation layer and corresponding to the third emission area;
a third color material covering a first end portion of the first color filter and a first end portion of the second color filter and having a same color as the third color filter; and
a color adjustment layer disposed on the encapsulation layer, wherein the color adjustment layer defines a first opening corresponding to the first emission area, a second opening corresponding to the second emission area, and a third opening corresponding to the third emission area, and the color adjustment layer is disposed to overlap the third color material.

15. The display apparatus of claim 14, wherein the color adjustment layer has a color different from the first color filter, the second color filter, and the third color filter.

16. The display apparatus of claim 14, wherein a height of the color adjustment layer is about 1 μm or less.

17. The display apparatus of claim 14, wherein the color adjustment layer comprises a yellow pigment or dye.

18. The display apparatus of claim 14, wherein a refractive index of the third color material is less than a refractive index of the first color filter and a refractive index of the second color filter.

19. The display apparatus of claim 14, further comprising:
an insulating layer disposed on the encapsulation layer,
wherein a lower surface of the first color filter, a lower surface of the second color filter, a lower surface of the third color filter, and a lower surface of the color adjustment layer are in direct contact with the insulating layer.

20. The display apparatus of claim 14, further comprising:
an overcoat layer disposed on the third color material,
wherein the color adjustment layer is disposed between the third color material and the overcoat layer.
